(19) United States
(12) Patent Application Publication
(10) Pub. No.: US 2026/0066024 A1
(43) Pub. Date: Mar. 5, 2026

(54) UNSELECTED BLOCK LEAKAGE MITIGATION IN A MEMORY DEVICE

(71) Applicant: Micron Technology, Inc., Boise, ID (US)

(72) Inventors: Avinash Rajagiri, Boise, ID (US); Ching-Huang Lu, Fremont, CA (US); Aman Gupta, Boise, ID (US); Shyam Sunder Raghunathan, Hyderabad (IN); Yingda Dong, Los Altos, CA (US)

(21) Appl. No.: 19/313,613

(22) Filed: Aug. 28, 2025

Related U.S. Application Data
(60) Provisional application No. 63/688,839, filed on Aug. 29, 2024.

(51) Int. Cl. G11C 29/12

(52) U.S. Cl. CPC G11C 29/12005; G11C 2029/1204

(57) ABSTRACT

A memory device includes a memory array with a plurality of memory cells formed at respective intersections of a plurality of wordlines and a plurality of bit lines. The memory device further control logic to initiate a program operation on one or more memory cells in a first block of the memory array, the program operation comprising a program phase, a program recovery phase, and a program exit phase. The control logic further causes a positive voltage pulse having a fixed duration to be applied to at least a subset of a plurality of bitlines of the memory array during the program exit phase of the program operation and causes the positive voltage pulse having the fixed duration to be applied to an access line controlling one or more drain-side select gate devices in the first block of the memory array during the program exit phase of the program operation.

### RELATED APPLICATIONS

This application claims the benefit of priority from U.S. Provisional Ser. No. 63/688,839, filed Aug. 29, 2024, the entire contents of which are hereby incorporated by reference herein.

### TECHNICAL FIELD

Embodiments of the disclosure relate generally to memory sub-systems, and more specifically, relate to unselected block leakage mitigation in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a flow diagram of an example method of unselected block leakage mitigation in a memory device of a memory sub-system in accordance with some embodiments of the present disclosure.

FIG. 4 is a diagram illustrating waveforms applied in the memory device for unselected block leakage mitigation in accordance with some embodiments of the present disclosure.

FIG. 5 is a diagram illustrating waveforms applied in the memory device for unselected block leakage mitigation in accordance with some embodiments of the present disclosure.

FIG. 6 is a diagram illustrating waveforms applied in the memory device for unselected block leakage mitigation in accordance with some embodiments of the present disclosure.

FIG. 7 is a block diagram of an example computer system in which embodiments of the present disclosure can operate.

### DETAILED DESCRIPTION

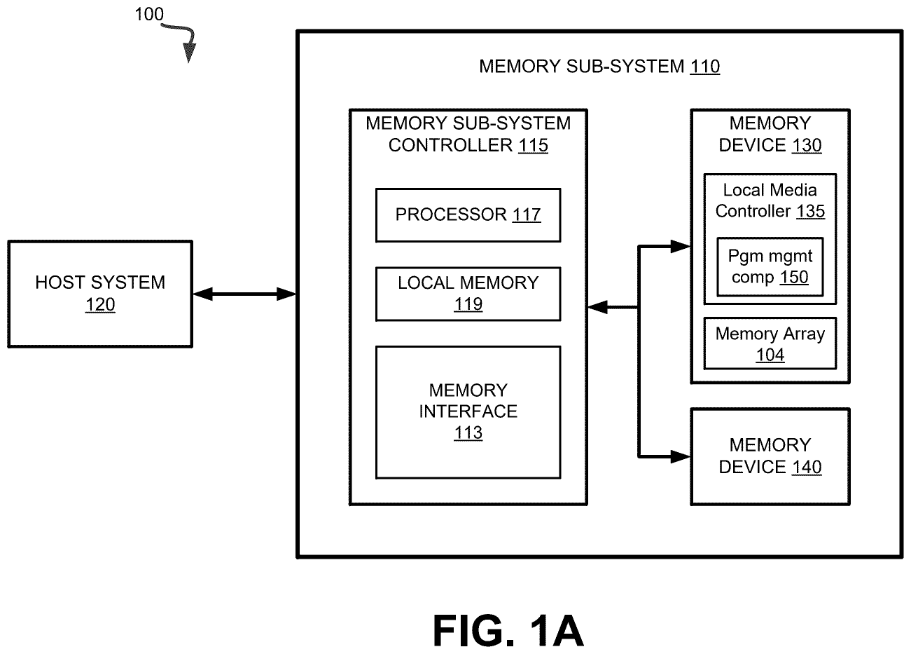

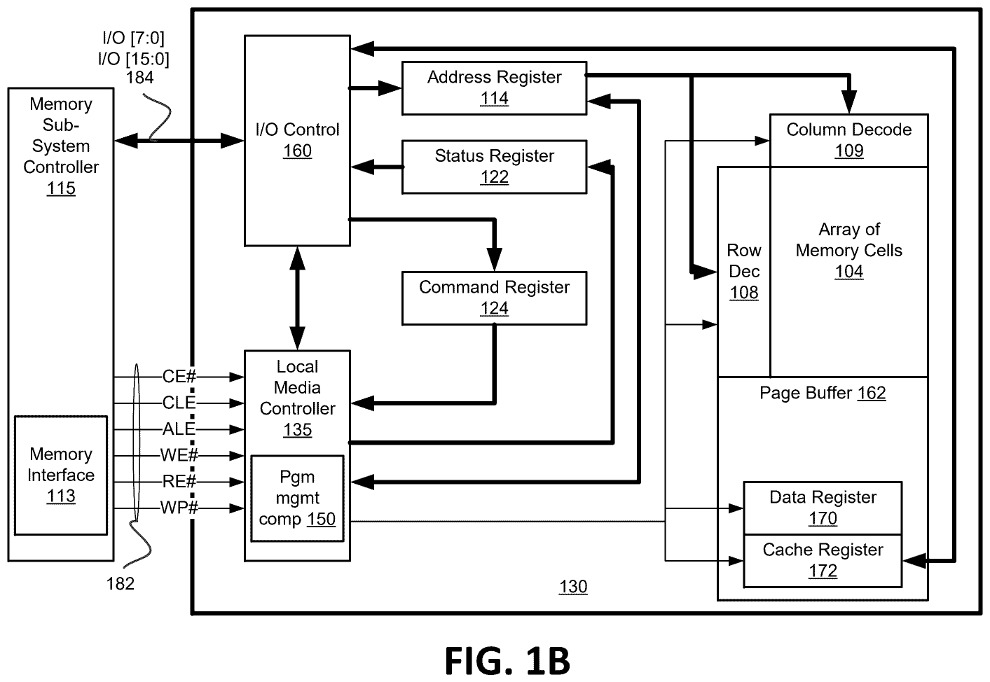

Aspects of the present disclosure are directed to unselected block leakage mitigation in a memory device of a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0”and “1”, or combinations of such values.

A memory device can be made up of bits arranged in a two-dimensional or a three-dimensional grid. Memory cells are formed onto a silicon wafer in an array of columns (also hereinafter referred to as bit lines) and rows (also hereinafter referred to as wordlines). A wordline can refer to one or more rows of memory cells of a memory device that are used with one or more bit lines to generate the address of each of the memory cells. The intersection of a bit line and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. Each data block can include a number of sub-blocks, where each sub-block is defined by an associated pillar (e.g., a vertical conductive trace) extending from a shared bitline. Since the sub-blocks can be accessed separately (e.g., to perform program or read operations), the data block can include a structure to selectively enable the pillar associated with a certain sub-block, while disabling the pillars associated with other sub-blocks. In one embodiment, this structure includes one or more select gate devices positioned at either or both ends of each pillar. Depending on a control signal applied, these select gate devices can either enable or disable the conduction of signals through the pillars. In one embodiment, the select gates devices associated with each pillar in the data block are controlled separately.

Certain memory devices can implement these select gate devices using replacement gate transistors, which have a relatively short channel. The replacement gate transistors are programmable devices and thus offer the benefit of more versatility but are susceptible to some amount of signal leakage. In addition, the programmable threshold voltage of replacement gate transistors can shift over time. While initially set at a certain target value, numerous factors including a number of program/erase cycles performed on the device, temperature changes, etc. can cause the threshold voltage of the select gate device to increase or decrease over time. This shift away from the target value can lead to charge loss or “leakage” causing the select gate device to function improperly, and potentially causing reliability problems in the data stored on the wordlines of the corresponding sub-block. For example, when one block of the memory device is being accessed (i.e., a selected block), one or more other blocks of the memory device that were previously programmed (i.e., unselected blocks) can suffer leakage due to being ineffectively cut-off from a shared bitline by the corresponding select gate devices. This leakage of charge from the unselected blocks to the shared bitline can impact sensing operations on the selected block, leading to an increased error rate. This is particularly true when the sensing operation (i.e., a read operation) occurs shortly after a previous program operation on the now unselected block. For example, at the end of the program operation, the voltage signal applied on the wordlines ramps down which further drives the channel potential in the pillar lower, and potentially to a negative voltage potential. Leakage from the channel onto the common bitline can impact read operations performed immediately thereafter (i.e., before the channel potential has a chance to stabilize). In addition, the leakage could also be suffered by non-programmable (e.g., MOS-type device) select gate devices. The turnaround time to re-tune the threshold voltage target for such MOS-type devices is long and can impact product development times. Furthermore, leakage can occur when the same block was previously programmed and subsequently read after a short delay. In this case, the negative channel potential can also be formed in the “selected-block,” but from a probability perspective this is less likely compared to case where the programmed/read blocks are different. Also, all the “unselected” blocks need not have been previously programmed, as the leakage can occur in any block from the same plane.

Aspects of the present disclosure address the above and other deficiencies by utilizing countermeasures designed for unselected block leakage mitigation in a memory device of a memory sub-system. In one embodiment, a new program exit phase is added to the conclusion of a program operation on the memory device. After the program phase when programming voltages are applied to selected wordlines associated with the memory cells to be programmed, and after a subsequent program recovery phase when those programming voltages are ramped back down, the program exit phase can be initiated. During the program exit phase, a bitline voltage signal applied to the bitlines in the memory device and a select gate device control signal applied to the select gate devices in the memory device are driven to a high voltage (e.g., Vcc or some other trimmable bias level) for a fixed duration. This high voltage signal on the bitline will create a relatively large potential difference between the bitline and the negative channel potential of those pillars associated with memory cells that were just programmed. The memory cells that were just programmed have an associated “selected” bitline and channels on every other block in the plane, which share the same bitline, manifest the negative channel potential during the programming and eventually contribute to the leakage. The differential pulls the channel potential up to a higher, non-negative, level that is closer to that of the channel potential of inhibited pillars that were not programmed during the previous program phase. In another embodiment, the select gate device control signal remains low so that the select gate devices remain off during the program exit phase. In some embodiments, including those when there is a longer delay between the program operation and the subsequent read operation, a similar high voltage pulse can be applied on the bitline at the beginning of the read operation, which has the same effect of increasing the channel potential that decreased over time due to charge leakage. This same high voltage pulse can be applied during any read operation, including those without a long program to read delay time.

Advantages of this approach include, but are not limited to, improved performance in the memory sub-system. The approach described herein can mitigate leakage in unselected blocks of the memory device which would otherwise negatively impact read operations performed shortly after a program operation. The mitigation reduces the error rate in the data read from the selected block without requiring physical changes to the select gate device structure in the memory device. This improves performance for low-latency read operations and improves overall quality of service provided to a host system.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, local media controller 135 of memory device 130 includes program management component 150. Program management component 150 can perform countermeasures to effect unselected block leakage mitigation in memory array 104. For example, during a program exit phase, program management component 150 can cause a bitline voltage signal applied to the bitlines in the memory array 104 and a select gate device control signal applied to the select gate devices in the memory array 104 to be driven to a high voltage (e.g., Vcc or some other trimmable bias level) for a fixed duration. This high voltage signal on the bitline will create a relatively large potential difference between the bitline and the negative channel potential of those pillars associated with memory cells that were just programmed. The differential pulls the channel potential up to a higher, non-negative, level that is closer to that of the channel potential of inhibited pillars that were not programmed during the previous program phase. In some embodiments, including those when there is a longer delay between the program operation and the subsequent read operation, program management component can cause a similar high voltage pulse can be applied on the bitline at the beginning of the read operation, which has the same effect of increasing the channel potential that decreased over time due to charge leakage. Further details with regards to the operations of program management component 150 and are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes program management component 150, which can implement countermeasures to reduce unselected block leakage mitigation in memory array 104, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer 162 of the memory device 130. The page buffer 162 may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

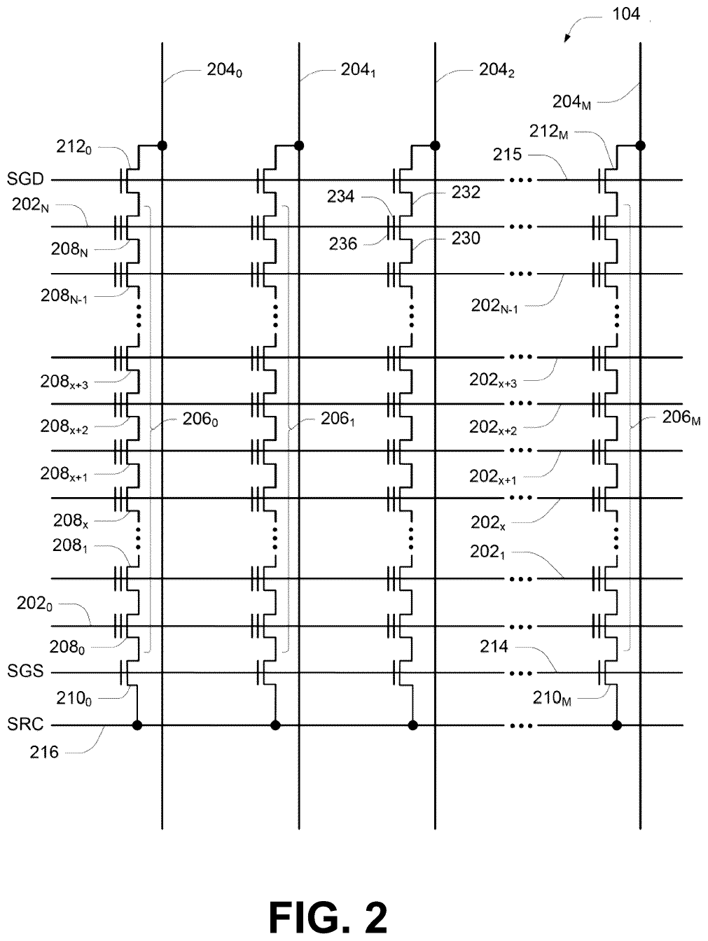

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

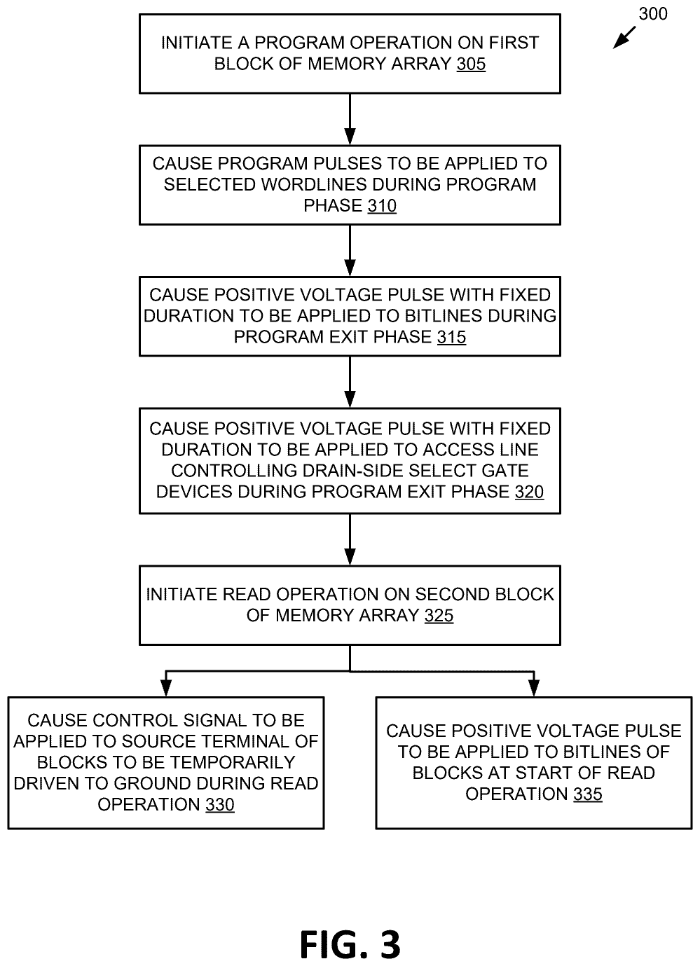

FIG. 3 is a flow diagram of an example method of unselected block leakage mitigation in a memory device of a memory sub-system in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by program management component 150 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

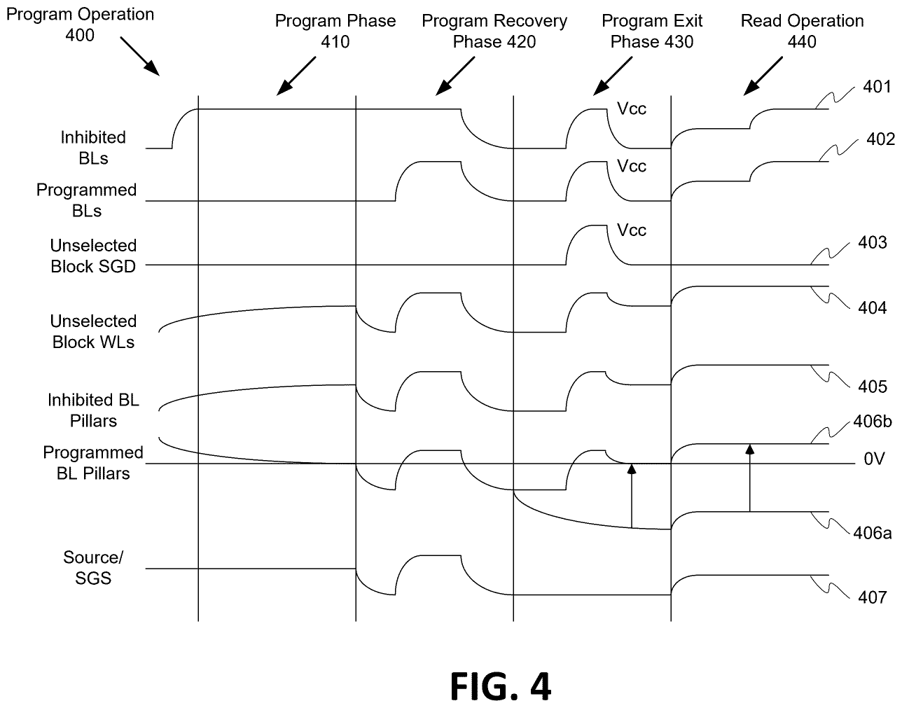

At operation 305, a program operation is initiated. For example, the processing logic (e.g., program management component 150) can initiate a program operation on one or more memory cells in a first block of a memory array 104, In one embodiment, the memory array 104 includes a plurality of memory cells formed at respective intersections of a plurality of wordlines and a plurality of bit lines. In one embodiment, the program operation comprises a number of phases, as illustrated in FIG. 4. For example, the program operation 400 can include a program phase 410 when the programming pulses are applied to selected wordlines associated with the memory cells to be programmed, a subsequent program recovery phase 420 when those programming voltages are ramped back down (e.g., to a ground voltage), and a program exit phase 430.

At operation 310, programming pulses are applied. For example, the processing logic can cause a plurality of programming pulses to be applied to selected wordlines corresponding to the one or more memory cells during the program phase 410 of the program operation 400. In one embodiment, each of the programming pulses are separated by one or more verify operations, and are applied to access lines (e.g., wordlines) associated with selected memory cells to program the selected memory cells to a respective target data states. After each programming pulse, one or more verify voltage levels are typically used to verify the programming of the selected memory cells. Programming typically uses many programming pulses in an incremental step pulse programming (ISPP) scheme, where each programming pulse is a single-level pulse that moves the memory cell threshold voltage by some amount.

At operation 315, a positive voltage pulse is applied. For example, the processing logic can cause a positive voltage pulse having a fixed duration to be applied to at least a subset of a plurality of bitlines of the memory array 104 during the program exit phase 430 of the program operation 400. In one embodiment, the positive voltage pulse having a fixed duration has a magnitude of at least one of a supply voltage in the memory device (e.g., Vcc) or a tunable bias level (e.g., some other positive voltage that can be adjusted to suit the specific implementation). Application of the positive voltage pulse is illustrated in FIG. 4. FIG. 4 is a diagram illustrating waveforms applied in the memory device for unselected block leakage mitigation in accordance with some embodiments of the present disclosure. In these embodiments, different signals are applied to various devices in memory device 130 in each of the illustrated phases (i.e., program phase 410, program recovery phase 420, and program exit phase 430). For example, program management component 150 can cause signals 401 and 402 to be applied to respective bitlines (BLs) in the memory device 130. Signal 401 is applied to inhibited bitlines (i.e., those bitlines corresponding to pillars in the memory array 104 associated with memory cells that are not being programmed as part of program operation 400) and signal 402 is applied to programmed bitlines (i.e., those bitlines corresponding to pillars in the memory array 104 associated with the one or more memory cells that were programmed as part of program operation 400). As illustrated in FIG. 4, signal 401 is high (e.g., at Vcc) during the program phase 410 and then is ramped down (e.g., to ground) during the program recovery phase 420, while signal 402 remains low during the program phase 410 and is temporarily increased, but then ramped down again during the program recovery phase 420. In one embodiment, at least the subset of the plurality of bitlines of the memory array 104 (i.e., those bitlines to which the positive voltage pulse is applied) comprises all bitlines of the memory array 104. As illustrated in FIG. 4, the positive voltage pulse is applied to both signal 401 and signal 402 during the program exit phase 430. Signals 401 and 402 are driven high for the fixed duration before being ramped back down again at the end of the program exit phase 430. In another embodiment, at least the subset of the plurality of bitlines of the memory array 104 comprises a number of bitlines corresponding to pillars in the memory array 104 associated with the one or more memory cells that were programmed. For example, in this embodiment, the positive voltage pulse may be applied only on signal 402, while signal 401 remains low during the program exit phase 430.

Referring again to FIG. 3, at operation 320, a positive voltage pulse is applied. For example, the processing logic can optionally cause the positive voltage pulse having the fixed duration to be applied to an access line controlling one or more drain-side select gate devices in the first block of the memory array 104 during the program exit phase 430 of the program operation 400. As illustrated in FIG. 4, signal 403 is applied to the drain-side select gate devices (SGDs), such as 212₀-212_{M}, to control their operation and cut-off the corresponding memory strings from the bitline. Signal 403 remains low throughout the program phase 410 and program recovery phase 420, such that the drain-side select gate devices remain off. The positive voltage pulse is applied to signal 403 during program exit phase 430, to temporarily turn on the drain-side select gate devices. In one embodiment, the positive voltage pulse applied on signal 403 is of the same magnitude and duration as the positive voltage pulse applied on signals 401 and 402. In other embodiments, however, the magnitude and duration of the positive voltage pulses may be different. Furthermore, in some embodiments, the positive voltage pulse is not applied to the drain-side select gate devise at all, and signal 403 remains low for the entirety of the program exit phase 430.

At operation 325, a read operation is initiated. For example, the processing logic can initiate a read operation on one or more memory cells in a second block of the memory array 104. In some embodiments, second block can be a different block than the first block and can be referred to as a “selected” block, while the first block can be referred to as an “unselected” block with respect to the read operation. In other embodiments, the second block can be the same as the first block. As illustrated in FIG. 4, the read operation 440 can follow the program exit phase 430 of the program operation 400. During the read operation 440, signals 401 and 402 are ramped up first to a pass voltage and then to a supply voltage, signal 403 remains low, and a read voltage signal 404 is observed on the wordlines of the unselected block (e.g., as a result of voltage coupling from the source bias or channel potential modulation). The voltage levels of pillars in the memory array 104 that are not associated with memory cells that were programmed are represented by signal 405 and the voltage levels of pillars that are associated with the one or more memory cells that were programmed are represented by signals 406a (without mitigation) and 406b (with mitigation). When programming pulses are applied, the signal 405 increases (e.g., close to Vcc), and since the wordlines are floating, the voltage of signal 404 will increase similarly. The signal 406a, however, decreases, as the potential is discharged to ground. When the WL voltage signal 404, which is floating, is coupled down to ground during the program recovery phase 420, it can couple to the voltage potential in the pillars that are associated with the programmed memory cells, causing signal 406a to be pulled even lower (i.e., to a negative voltage level). The application of the positive voltage pulses in signals 401, 402, and 403 during the program exit phase 430, however, creates a large potential difference between the bitlines and the negative channel potential, thereby pulling up the channel potential so that it no longer negative, as shown in signal 406b. Thus, during read operation 440, there will be fewer read errors attributable to leakage from the channel into the bitline. The signal 407 at the source-side select gate devices can remain low during program exit phase 430 before being ramped up during the read operation 440.

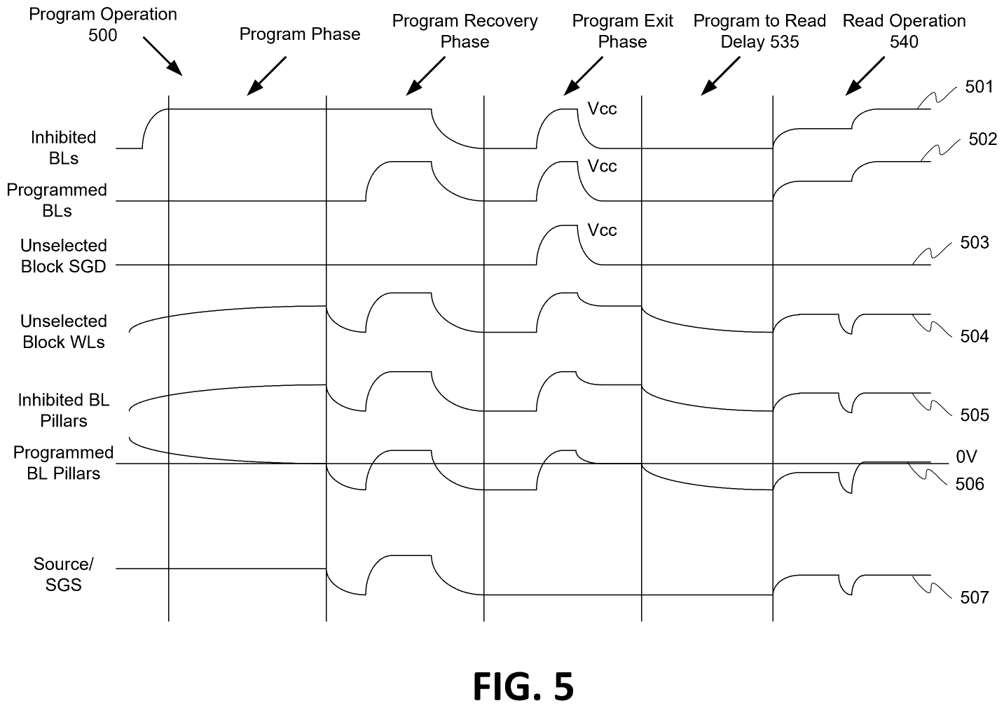

Referring again to FIG. 3, at operation 330, a control signal is underdriven. For example, the processing logic can cause a control signal applied to a source terminal of each block of the memory array to be temporarily driven to a ground voltage during the read operation. One example of this signal, which may be common to all blocks in the same plane, is shown in FIG. 5. The source underdrive approach is particularly effective when there is a significant time delay 535 between the end of program operation 500 and the start of a subsequent read operation 540. In one embodiment, signal 507 is applied to the source terminal 216 of the memory device 130 and/or to the control the source-side select gate devices, such as 210₀-210_{M}. In one embodiment, when the signals 501 and 502 applied to the respective bitlines are ramped up to the supply voltage during the read operation 540, signal 507 can be driven low (e.g., to GND or some other lower trimmable bias) for a short period of time. This underdrive can cause the floating wordlines to also be pulled down, as shown in signal 504, as well as the channel potential in the memory pillars, as shown in signal 505 and 506. The SGD signal 503 remains low. The resulting differential between the negative channel potential of the pillars that are associated with the programmed memory cells, as shown by signal 506, and the voltage on the respective bitlines drives electrons out of the pillars and raises the channel potential (i.e., to a non-negative level). Thus, during read operation 540 performed after program to read delay 535, there will be fewer read errors attributable to leakage from the channel into the bitline. Although FIG. 5 illustrates the source signal underdrive approach being used in conjunction with the positive voltage pulse applied during the program exit phase, it should be understood that both approaches can be used independently of one another and can be either enabled or disabled depending on the implementation.

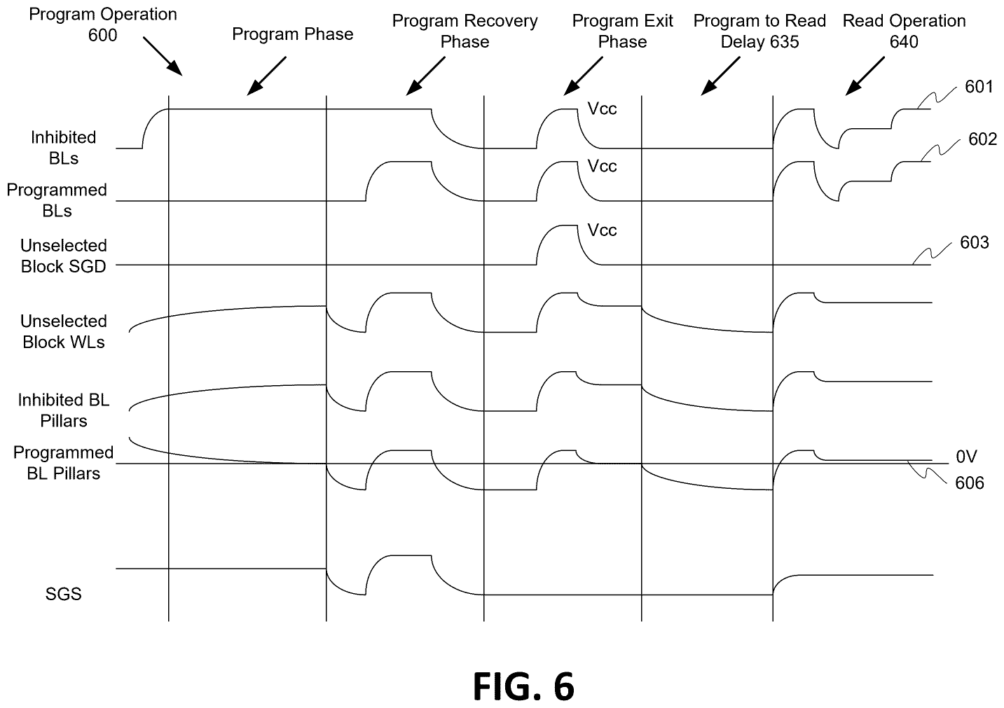

As an alternative, at operation 335, a positive voltage pulse is applied. For example, the processing logic can cause the positive voltage pulse having the fixed duration to be applied to at least the subset of the plurality of bitlines shared among the blocks of the memory array at a start of the read operation. One example of this is shown in FIG. 6. This approach is similarly effective when there is a significant time delay 635 between the end of program operation 600 and the start of a subsequent read operation 640. In one embodiment, at the start of a read operation 640, program management component 150 can cause the positive voltage pulse to be applied to the respective bitlines, as shown in signals 601 and 602. Signal 603 applied to the drain-side select gate device remains low in one embodiment, however. In another embodiment, signal 603 is driven high. In one embodiment, the positive voltage pulse having a fixed duration has a magnitude of at least one of a supply voltage in the memory device (e.g., Vcc) or a tunable bias level (e.g., some other positive voltage that can be adjusted to suit the specific implementation). The application of the positive voltage pulses in signals 601 and 602 during the read operation 640 creates a large potential difference between the bitlines and the negative channel potential in the pillars that are associated with the programmed memory cells, thereby pulling up the channel potential so that it is no longer negative, as shown in signal 606. Thus, during read operation 640, there will be fewer read errors attributable to leakage from the channel into the bitline. Although FIG. 6 illustrates the positive voltage pulse applied during the read operation being used in conjunction with the positive voltage pulse applied during the program exit phase, it should be understood that both approaches can be used independently of one another and can be either enabled or disabled depending on the implementation.

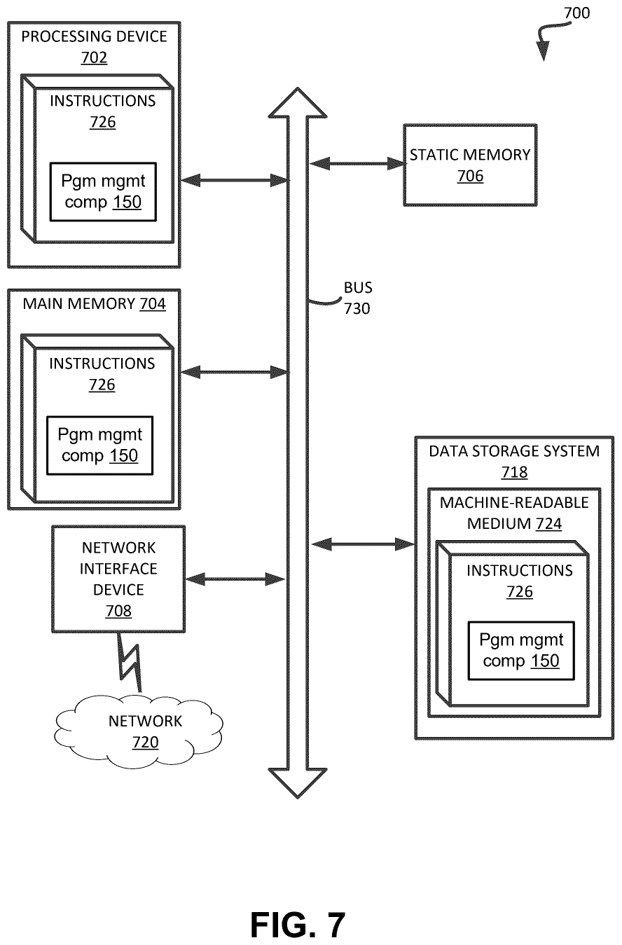

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to program management component 150 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1A.

In one embodiment, the instructions 726 include instructions to implement functionality corresponding to the program management component 150 of FIG. 1A. While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells formed at respective intersections of a plurality of wordlines and a plurality of bitlines; and
control logic, operatively coupled with the memory array, to perform operations comprising:
initiating a program operation on one or more memory cells in a first block of the memory array, the program operation comprising a program phase, a program recovery phase, and a program exit phase;
causing a positive voltage pulse having a fixed duration to be applied to at least a subset of the plurality of bitlines of the memory array during the program exit phase of the program operation; and
causing the positive voltage pulse having the fixed duration to be applied to an access line controlling one or more drain-side select gate devices in the first block of the memory array during the program exit phase of the program operation.

2. The memory device of claim 1, wherein at least the subset of the plurality of bitlines of the memory array comprises all bitlines of the memory array.

3. The memory device of claim 1, wherein at least the subset of the plurality of bitlines of the memory array comprises a number of bitlines corresponding to pillars in the memory array associated with the one or more memory cells that were programmed.

4. The memory device of claim 1, wherein the positive voltage pulse having the fixed duration has a magnitude of at least one of a supply voltage in the memory device or a tunable bias level.

5. The memory device of claim 1, wherein the control logic is to perform operations further comprising:
initiating a read operation on one or more memory cells in a second block of the memory array.

6. The memory device of claim 5, wherein the control logic is to perform operations further comprising:
causing a control signal applied to a source terminal of the memory array to be temporarily driven to a ground voltage during the read operation.

7. The memory device of claim 5, wherein the control logic is to perform operations further comprising:
causing the positive voltage pulse having the fixed duration to be applied to at least the subset of the plurality of bitlines of the memory array at a start of the read operation.

8. A method comprising:
initiating a program operation on one or more memory cells in a first block of a memory array of a memory device, the program operation comprising a program phase, a program recovery phase, and a program exit phase;
causing a positive voltage pulse having a fixed duration to be applied to at least a subset of a plurality of bitlines of the memory array during the program exit phase of the program operation; and
causing the positive voltage pulse having the fixed duration to be applied to an access line controlling one or more drain-side select gate devices in the first block of the memory array during the program exit phase of the program operation.

9. The method of claim 8, wherein at least the subset of the plurality of bitlines as of the memory array comprises all bitlines of the memory array.

10. The method of claim 8, wherein at least the subset of the plurality of bitlines of the memory array comprises a number of bitlines corresponding to pillars in the memory array associated with the one or more memory cells that were programmed.

11. The method of claim 8, wherein the positive voltage pulse having the fixed duration has a magnitude of at least one of a supply voltage in the memory device or a tunable bias level.

12. The method of claim 8, further comprising:
initiating a read operation on one or more memory cells in a second block of the memory array.

13. The method of claim 12, further comprising:
causing a control signal applied to a source terminal of the memory array to be temporarily driven to a ground voltage during the read operation.

14. The method of claim 12, further comprising:
causing the positive voltage pulse having the fixed duration to be applied to at least the subset of the plurality of bitlines of the memory array at a start of the read operation.

15. A memory device comprising:
a memory array comprising a plurality of memory cells formed at respective intersections of a plurality of wordlines and a plurality of bitlines; and
control logic, operatively coupled with the memory array, to perform operations comprising:
initiating a program operation on one or more memory cells in a first block of the memory array;
causing a plurality of programming pulses to be applied to selected wordlines corresponding to the one or more memory cells during the program operation; and
causing a positive voltage pulse having a fixed duration to be applied to at least a subset of the plurality of bitlines of the memory array and to an access line controlling one or more drain-side select gate devices in the first block of the memory array after one or more of the plurality of programming pulses during the program operation.

16. The memory device of claim 15, wherein at least the subset of the plurality of bitlines of the memory array comprises at least one of all bitlines of the memory array or a number of bitlines corresponding to pillars in the memory array associated with the one or more memory cells that were programmed.

17. The memory device of claim 15, wherein the positive voltage pulse having the fixed duration has a magnitude of at least one of a supply voltage in the memory device or a tunable bias level.

18. The memory device of claim 15, wherein the control logic is to perform operations further comprising:
initiating a read operation on one or more memory cells in a second block of the memory array.

19. The memory device of claim 18, wherein the control logic is to perform operations further comprising:
causing a control signal applied to a source terminal of the memory array to be temporarily driven to a ground voltage during the read operation.

20. The memory device of claim 18, wherein the control logic is to perform operations further comprising:
causing the positive voltage pulse having the fixed duration to be applied to at least the subset of the plurality of bitlines of the memory array at a start of the read operation.
